(19) United States
(12) Patent Application Publication
(10) Pub. No.: US 2013/0170130 A1
(43) Pub. Date: Jul. 4, 2013

(54) ELECTRONIC APPARATUS AND CARRYING STRUCTURE THEREOF

(71) Applicant: PEGATRON CORPORATION, Taipei City (TW)

(72) Inventors: Wei-Chih LAI, Taipei City (TW); Kuang-Jui CHENG, Taipei City (TW); Yung-Sheng LEE, Taipei City (TW); Chien-Feng MA, Taipei City (TW); Tien-Wen LIN, Taipei City (TW)

(73) Assignee: PEGATRON CORPORATION, Taipei City (TW)

(21) Appl. No.: 13/724,935

(22) Filed: Dec. 21, 2012

(30) Foreign Application Priority Data
Dec. 30, 2011 (TW) 100225102

(51) Int. Cl. H05K 5/02; H05K 7/14

(52) U.S. Cl. CPC H05K 5/0221; H05K 7/14
USPC 361/679.33; 361/679.01; 312/223.1

(57) ABSTRACT

A carrying structure is used to fix an electronic element on a casing. The carrying structure includes a main body, a blocking part and a hooking part. The main body is fixed on the casing and has an accommodating space for accommodating the electronic element. The blocking part is disposed on one side of the main body and used to block the electronic element from moving vertically. The hooking part is disposed on another side of the main body. When the electronic element is pushed in the accommodating space, one end of the electronic element enters the blocking part and the other end of the electronic element presses the hooking part. Accordingly, the electronic element is accommodated in the accommodating space, and the hooking part hooks the other end of the electronic element.

### CROSS REFERENCE TO RELATED APPLICATIONS

This Non-provisional application claims priority under 35 U.S.C. §119(a) on Patent Application No(s). 100225102 filed in Taiwan, Republic of China on Dec. 30, 2011, the entire contents of which are hereby incorporated by reference.

### BACKGROUND

1. Technology Field

The present disclosure relates to an electronic apparatus and a carrying structure thereof, and in particular, to a carrying structure for carrying and fixing an electronic element, and an electronic apparatus containing the carrying structure.

2. Related Art

As the progress of technology, the personal computer (PC) has become the essential product in every family. In recent years, an all-in-one PC is provided to improve the conventional desktop computer, which is heavy and hard to move and transportation, and needs a lot of additional cables. The all-in-one PC integrates the computer host and the monitor as well as the peripheral devices such as the optical disk drive and speaker, so that the number of cables connecting separated devices can be reduced or omitted. In order to achieve the portability, the casing of the all-in-one PC is usually designed as compact as possible. Thus, the internal space of the casing for the all-in-one PC is so limited that the electronic elements inside the casing must be arranged very closely.

FIG. 1 is a schematic diagram showing a conventional all-in-one PC 1, which includes a main board 11, a hard disk drive 12, an optical disk drive 13, at least one heat-dissipation device 14 and a casing 15. The main board 11, the hard disk drive 12, the optical disk drive 13 and the heat-dissipation device 14 are configured within the casing 15. The conventional optical disk drive 13 is installed horizontally in the casing 15 and then screwed on the casing 15. However, the internal space of the casing 15 is limited, so that the installation or replacement of the optical disk drive 13 is very inconvenient. For example, before installing or removing the optical disk drive 13, some other electronic elements (e.g. the heat-dissipation device 14) must be disassembled. This is very inconvenient for the user or manufacturer, and it will spend more time to install or disassemble the electronic elements.

### SUMMARY OF THE INVENTION

The present disclosure is to provide an electronic apparatus and a carrying structure thereof that allows to easily install the electronic element to the carrying structure or to easily disassemble the electronic element from the carrying structure, thereby reducing the assembling time, enhancing the convenience, and improving the connection and assembling strength between the carrying structure and the electronic element.

A carrying structure of this disclosure is used to fix an electronic element on a casing, and includes a main body, a blocking part and a hooking part. The main body is fixed on the casing and has an accommodating space for accommodating the electronic element. The blocking part is disposed on one side of the main body and configured to block the electronic element from moving vertically. The hooking part is disposed on another side of the main body. When the electronic element is pushed in the accommodating space, one end of the electronic element enters the blocking part and the other end of the electronic element presses the hooking part, so that the electronic element is accommodated in the accommodating space, and the hooking part hooks the other end of the electronic element.

In addition, an electronic apparatus of the disclosure includes a casing and a carrying structure, which is used to fix an electronic element on the casing. The carrying structure includes a main body, a blocking part and a hooking part. The main body is fixed on the casing and has an accommodating space for accommodating the electronic element. The blocking part is disposed on one side of the main body and configured to block the electronic element from moving vertically. The hooking part is disposed on another side of the main body. When the electronic element is pushed in the accommodating space, one end of the electronic element enters the blocking part and the other end of the electronic element presses the hooking part, so that the electronic element is accommodated in the accommodating space, and the hooking part hooks the other end of the electronic element.

In one embodiment of this disclosure, the electronic element is an optical disk drive, a hard disk drive or other electronic devices.

In one embodiment of this disclosure, the blocking part has an opening, and the one end of the electronic element enters the blocking part through the opening.

In one embodiment of this disclosure, the casing has a sliding slot, a first opening and a second opening, and the main body correspondingly has a sliding rail, a first protrusion and a second protrusion, which are disposed corresponding to the sliding slot, the first opening and the second opening for fixing the main body on the casing.

In one embodiment of this disclosure, the main body further has a hand-held portion.

As mentioned above, the electronic apparatus and carrying structure of the disclosure is used to fix an electronic element. The carrying structure includes a main body, a blocking part and a hooking part. When the electronic element is pushed in the accommodating space, one end of the electronic element enters the blocking part until the blocking part cover a part of the electronic element, so that the electronic element will not be moved by external force. Besides, the other end of the electronic element presses the hooking part, so that the electronic element is accommodated in the accommodating space, and the hooking part hooks the other end of the electronic element, thereby firmly fixing the electronic element.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing a conventional all-in-one PC;

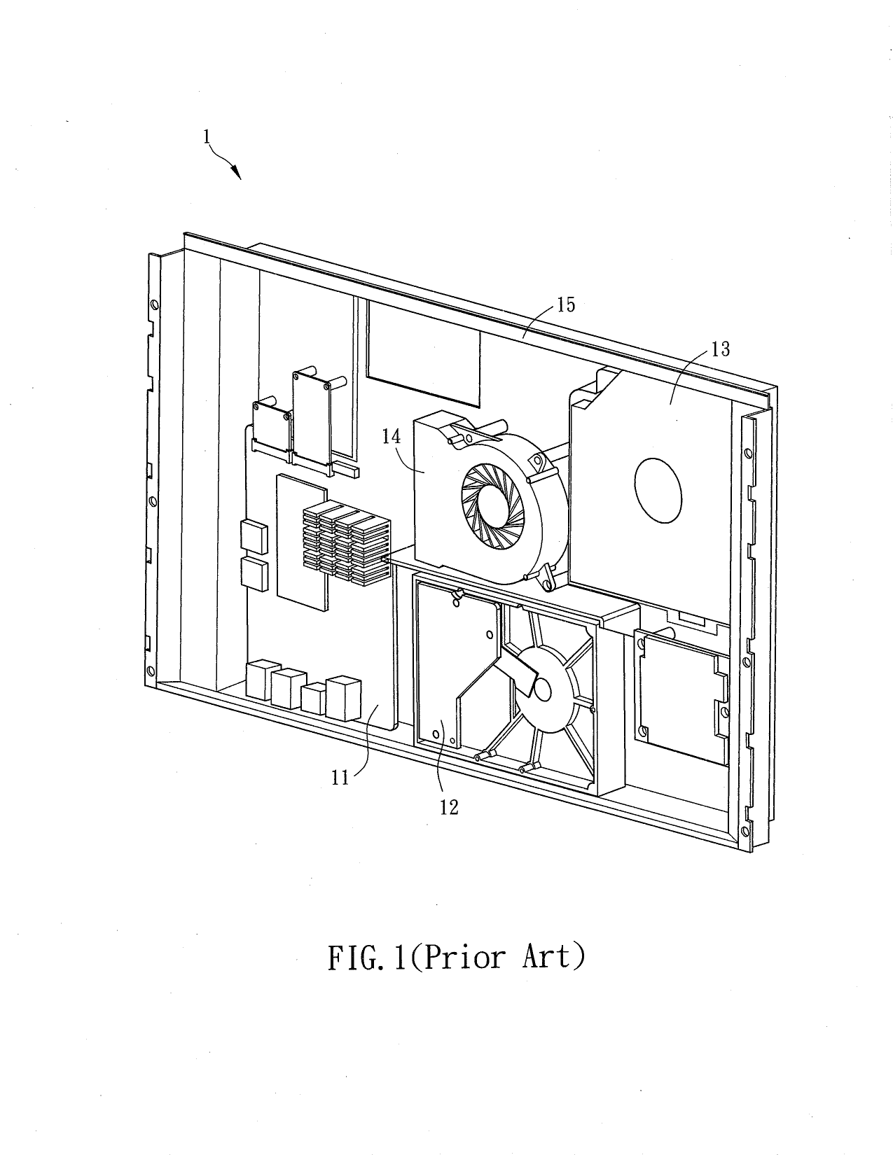

FIG. 2 is a schematic diagram showing an electronic element and a carrying structure according to a preferred embodiment of the disclosure;

FIG. 3 is a schematic diagram showing the assembled electronic element and carrying structure of FIG. 2;

FIG. 4 is another schematic diagram viewing from the opposite side of the electronic element and carrying structure according to the preferred embodiment of the disclosure;

FIG. 5 is a schematic diagram showing an electronic element, a casing and a carrying structure according to the preferred embodiment of the disclosure; and

FIG. 6 is a sectional view of the assembled electronic element, casing and carrying structure of FIG. 5.

### DETAILED DESCRIPTION OF THE INVENTION

The present invention will be apparent from the following detailed description, which proceeds with reference to the accompanying drawings, wherein the same references relate to the same elements.

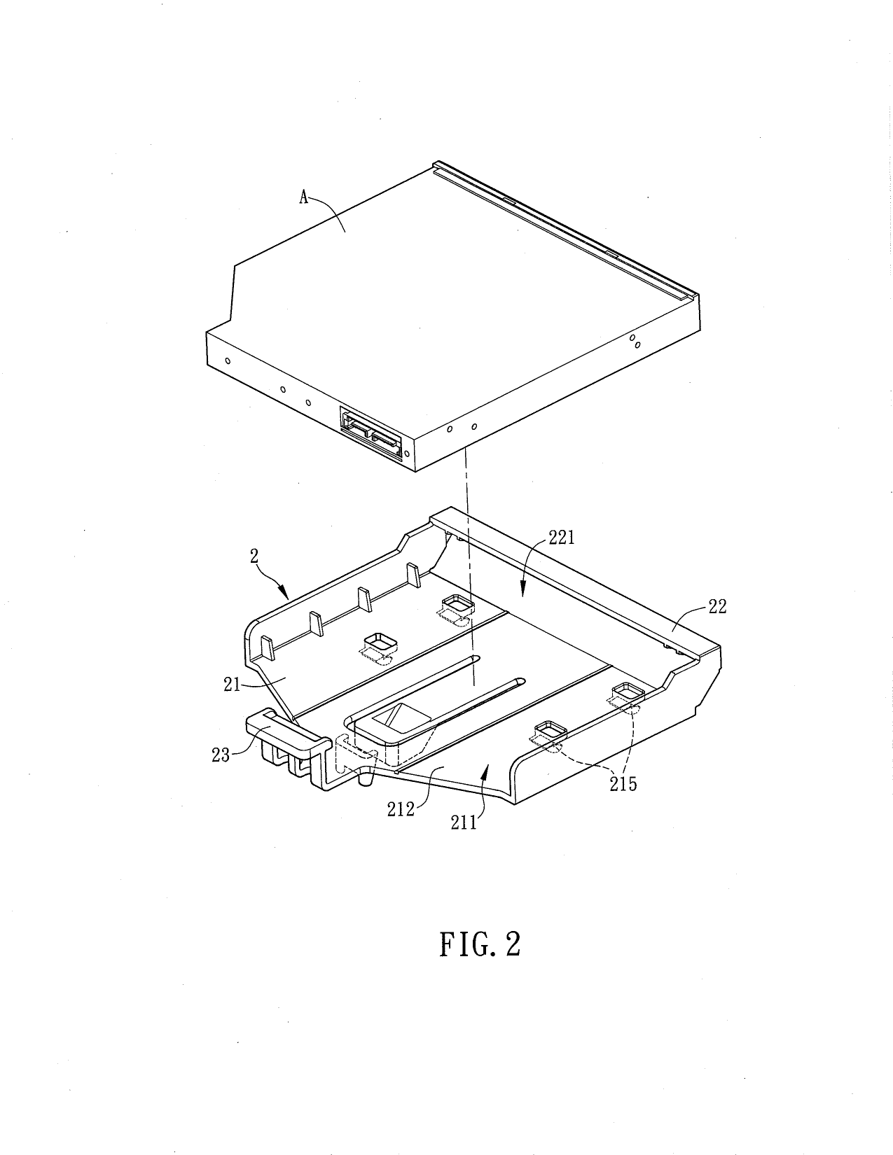

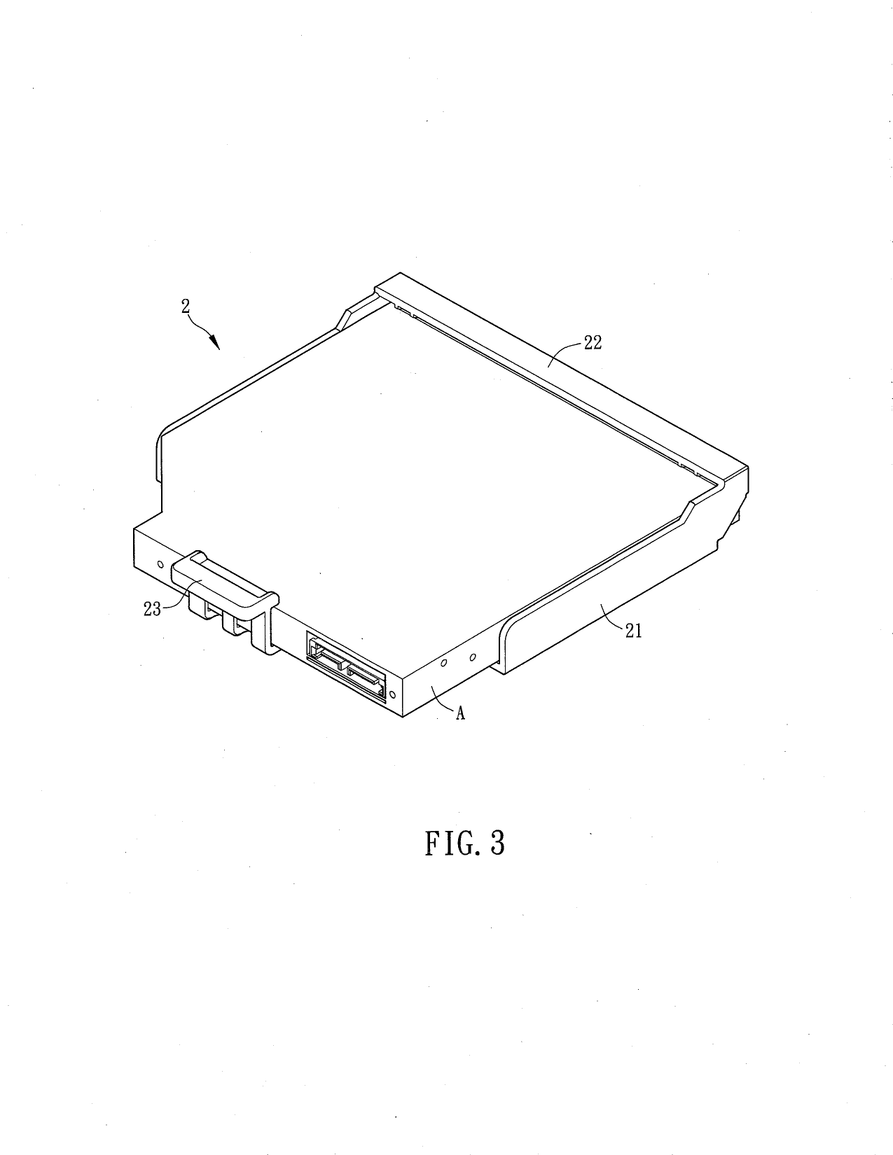

FIG. 2 is a schematic diagram showing an electronic element A and a carrying structure 2 according to a preferred embodiment of the disclosure, and FIG. 3 is a schematic diagram showing the assembled electronic element A and the carrying structure 2 of FIG. 2. As shown in FIGS. 2 and 3, the carrying structure 2 is used to fix the electronic element A on a casing (not shown). The electronic element A is, for example, an optical disk drive (ODD), a hard disk drive (HDD), or other electronic elements. In this embodiment, the electronic element A is, for example but not limited to, an ODD. The carrying structure 2 includes a main body 21, a blocking part 22, and a hooking part 23.

The main body 21 is fixed on the casing and has an accommodating space 211 for accommodating the electronic element A. The dimension and type of the main body 21 can be designed corresponding to those of the electronic element A. This is not to limit the present disclosure, and for example, the type of the main body 21 can be designed based on the environment and appearance of the carrying structure 2.

The blocking part 22 is disposed on one side of the main body 21 and used to block the electronic element A, which is disposed in the accommodating space 211, from moving vertically. The dimension of the blocking part 22 is also designed corresponding to the electronic element A. Accordingly, when the electronic element A is disposed in the accommodating space 211 of the main body 21, the blocking part 22 can cover a part of the electronic element A and fix the electronic element A, so that the electronic element A will not be easily moved by external force. The blocking part 22 has an opening 221, and one end of the electronic element A enters the opening 221 and then disposed on the blocking part 22. Moreover, the blocking part 22 may further include a slot (not shown), which is disposed opposite to the opening of the ODD (the electronic element A). After the ODD is disposed on the carrying structure 2, the user can insert an optical disk (CD/DVD) into the ODD through the slot of the blocking part 22. Then, the ODD can read the inserted optical disk. To be noted, in other embodiments, when the carrying structure is used to fix a HDD or other electronic elements, the blocking part may be configured without the slot.

The hooking part 23 is disposed on another side of the main body 22, which is opposite to the blocking part 22. In this embodiment, the hooking part 23 can hook another end of the electronic element A and thus fix it. To disassemble the electronic element A from the carrying structure 2, the user can hold the hooking part 23 and slightly pull it backwardly so as to remove the electronic element A.

In more specific, the electronic element A is disposed on the carrying structure 2 in a vertical direction. As shown in FIG. 2, the electronic element A is pushed in the accommodating space 211 of the main body 21 from the top of the carrying structure 2. When the electronic element A is pushed in the accommodating space 211, one end of the electronic element A enters the blocking part 22 until the blocking part 22 covers a part of the electronic element A, and the other end of the electronic element A presses the hooking part 23. Accordingly, the electronic element A is accommodated in the accommodating space 211, and the hooking part 23 hooks the other end of the electronic element A, so that the electronic element A can be firmly fixed. If the electronic element A is an ODD, the one end of the electronic element A indicates the end configured with an opening.

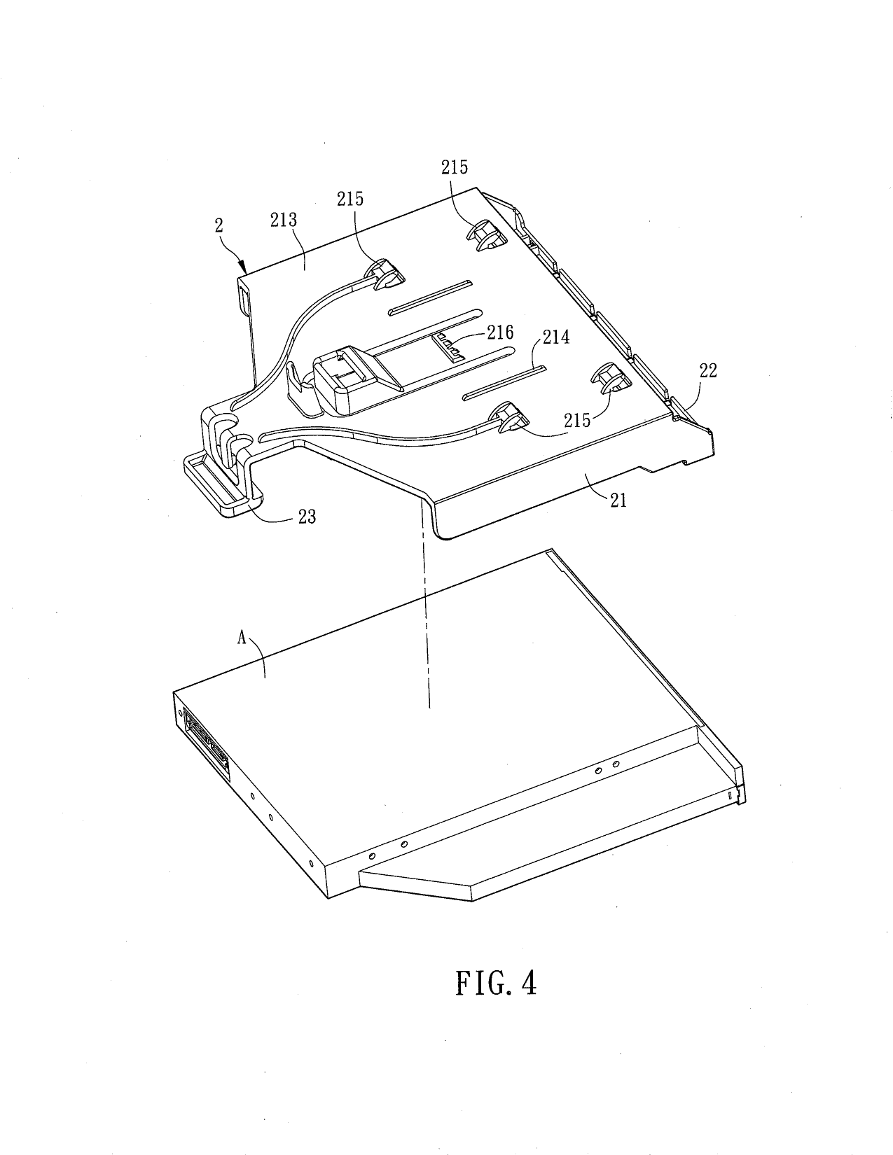

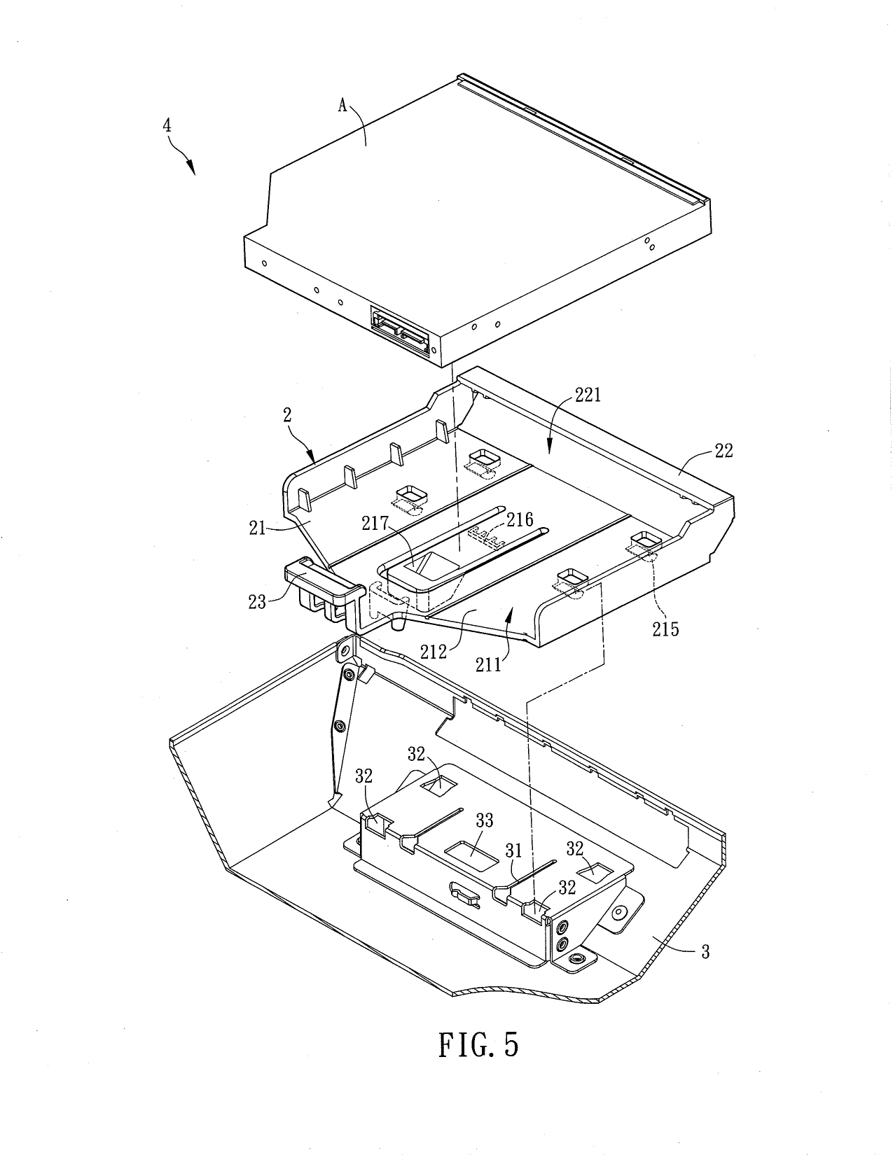

FIG. 4 is another schematic diagram viewing from the opposite side of the electronic element and carrying structure according to the preferred embodiment of the disclosure, and FIG. 5 is a schematic diagram showing an electronic element, a casing and a carrying structure according to the preferred embodiment of the disclosure. Referring to FIGS. 4 and 5, the carrying structure 2 is disposed within an electronic apparatus 4 and connected with a casing 3 of the electronic apparatus 4. In one embodiment, the carrying structure and casing can be integrally formed. Otherwise, in other embodiments, the carrying structure and casing are individual components and can be assembled together. In this embodiment, the carrying structure 2 and casing 3 are individual components and can be assembled together by hooking or sliding connection.

The main body 21 has a first surface 212 (see FIG. 2) and a second surface 213 (see FIG. 4), and the first surface 212 is opposite to the second surface 213. In this case, the blocking part 22 and the hooking part 23 are disposed on the first surface 212 of the main body 21. In addition, the main body 21 further includes a sliding rail 214, a first protrusion 215, and a second protrusion 216, which are all disposed on the second surface 213 of the main body 21. In the present embodiment, the main body 21 totally includes two sliding rails 214, four first protrusions 215, and a second protrusion 216. To be noted, the numbers, positions, shapes and sizes of the sliding rail 214, first protrusion 215 and second protrusion 216 are not limited in this disclosure. Moreover, the main body 21 of this embodiment may further include a hand-held part 217. The user can put his/her fingers on the hand-held part 217 and the hooking part 23 to easily grab the carrying structure 2 and then to disassemble the carrying structure 2 from the casing 3 or to install the carrying structure 2 on the casing 3 conveniently.

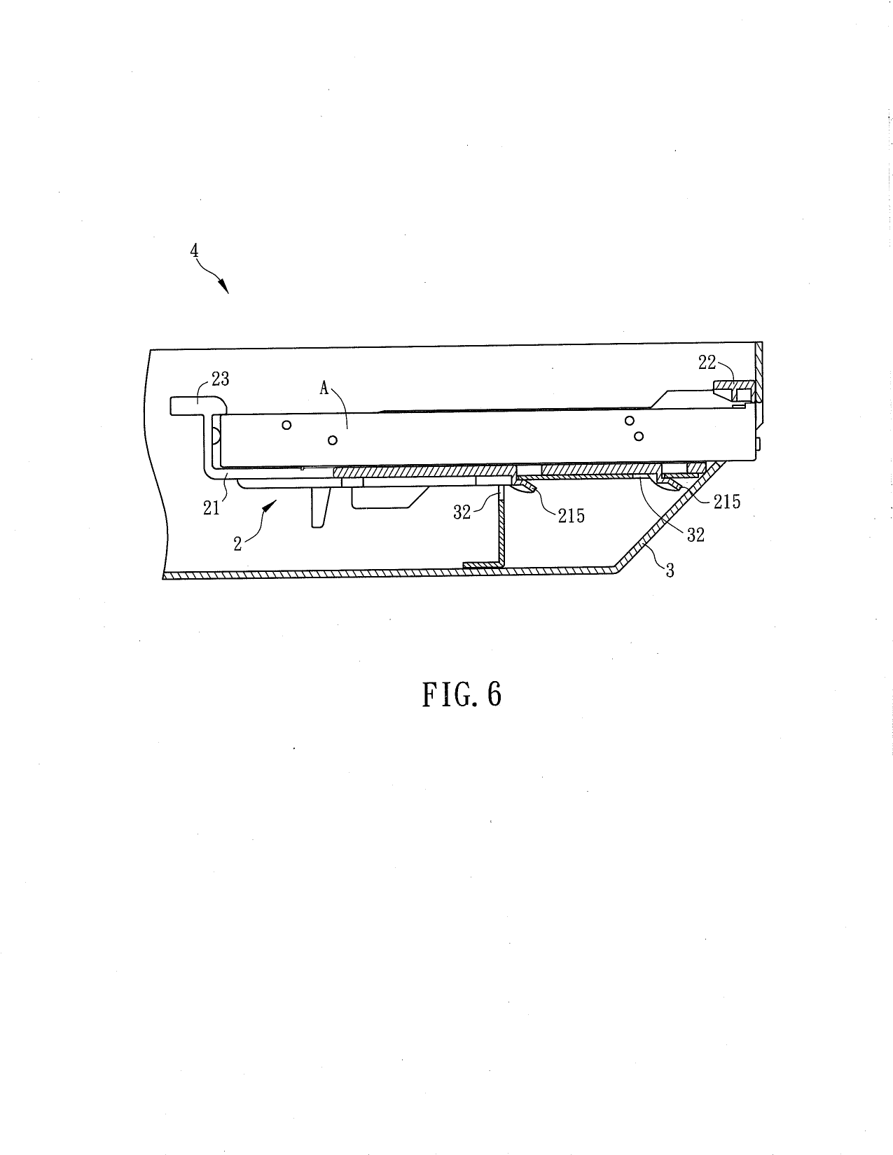

FIG. 6 is a sectional view of the assembled electronic element, casing and carrying structure of FIG. 5. The casing 3 has a sliding slot 31, a first opening 32, and a second opening 33. In this embodiment, the casing 3 has two sliding slots 31, four first openings 32, and a second opening 33. To be noted, the numbers, positions, shapes and sizes of the sliding slot 31, first opening 32 and second opening 33 are not limited in this disclosure. Herein, the numbers and positions of the sliding slot 31, first opening 32 and second opening 33 of the casing 3 are configured corresponding to those of the sliding rail 214, first protrusion 215 and second protrusion 216 of the main body 2.

The structures of the carrying structure 2 and the casing 3 of this disclosure have been described hereinabove, and the real application of the carrying structure 2 will be illustrated hereinafter with reference to FIGS. 2 to 6. The following illustration will discuss the processes for installing the carrying structure 2 on the casing 3 and disposing the electronic element A on the carrying structure 2.

Firstly, the carrying structure 2 is installed on the casing 3, so that they are connected to each other. In this installation process, the user holds the hand-held part 217 and the hooking part 23, and then aligns the carrying structure 2 with the casing 3, so that the sliding rail 214, the first protrusion 215 and the second protrusion 216 of the carrying structure 2 are disposed opposite to the sliding slot 31, the first opening 32 and the second opening 33 of the casing, respectively. Afterwards, the sliding rail 214 is slid into the sliding slot 31, so the first protrusion 215 and the second protrusion 216 are fixed in the first opening 32 and the second opening 33, respectively. This configuration can enhance the connection strength between the casing 3 and the carrying structure 2, and fix the relative positions thereof.

Next, the electronic element A is disposed on the carrying structure 2 along the vertical direction. For example, as shown in FIG. 5, the electronic element A is pushed into the carrying structure 2 from the top and then enters the accommodating space 211 of the main body 21. When the electronic element A is pushed in the accommodating space 211, one end of the electronic element A enters the blocking part 22 until the blocking part 22 covers a part of the electronic element A, and the other end of the electronic element A presses the hooking part 23. Accordingly, the electronic element A is accommodated in the accommodating space 211, and the hooking part 23 hooks the other end of the electronic element A, so that the electronic element A can be firmly fixed. Herein, if the electronic element A is an ODD, the one end of the electronic element A indicates the end configured with an opening. When the electronic element A is to be replaced or renewed, it is possible to remove the, electronic element A from the carrying structure 2 by slightly pushing the hooking part 23 toward the direction away from the electronic element A.

With reference to FIGS. 5 and 6, the present disclosure also provides an electronic apparatus 4, which includes a casing 3 and a carrying structure 2. The electronic apparatus 4 can be, for example but not limited to, an all-in-one desktop computer, a laptop computer or other foldable electronic devices. In this embodiment, the electronic apparatus 4 is an all-in-one desktop computer.

The carrying structure 2 is used to fix an electronic element A on the casing 3. The carrying structure 2 includes a main body 21, a blocking part 22, and a hooking part 23. The main body 21 is fixed on the casing 3 and has an accommodating space 211 for accommodating the electronic element A. The blocking part 22 is disposed on one side of the main body 21 and used to block the electronic element A from moving vertically. The hooking part 23 is disposed on another side of the main body 21. When the electronic element A is pushed in the accommodating space 211, one end of the electronic element A enters the blocking part 22 and the other end of the electronic element A presses the hooking part 23. Accordingly, the electronic element A is accommodated in the accommodating space 211, and the hooking part 23 hooks the other end of the electronic element A.

The technical features of the casing 3, carrying structure 2 and electronic element A have been describe hereinabove, so the detailed descriptions thereof will be omitted here.

In summary, the electronic apparatus and carrying structure of the disclosure is used to fix an electronic element. The carrying structure includes a main body, a blocking part and a hooking part. When the electronic element is pushed in the accommodating space, one end of the electronic element enters the blocking part until the blocking part cover a part of the electronic element, so that the electronic element will not be moved by external force. Besides, the other end of the electronic element presses the hooking part, so that the electronic element is accommodated in the accommodating space, and the hooking part hooks the other end of the electronic element, thereby firmly fixing the electronic element. Thus, it is possible to remove the electronic element from the carrying structure by slightly pushing the hooking part toward the direction away from the electronic element. Accordingly, the user can easily retrieve the electronic element from the carrying structure. In addition, the carrying structure has the sliding rail, first protrusion, and second protrusion, which are configured to corresponding connect with the sliding slot, first opening, and second opening of the casing, so that the carrying structure can be fixed on the casing of the electronic apparatus.

Compared with the conventional art, the electronic apparatus and carrying structure of the disclosure can easily fix an electronic element on the carrying structure without using the conventional connecting means, such as screws, so that the electronic element can also be easily disassembled from the carrying structure. This feature can reduce the assembling and disassembling time and thus improve the operation convenience. Moreover, the present disclosure can further enhance the connection strength between the casing, carrying structure and electronic element.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A carrying structure used to fix an electronic element on a casing, the carrying structure comprising:
a main body fixed on the casing and having an accommodating space for accommodating the electronic element;
a blocking part disposed on one side of the main body and configured to block the electronic element from moving vertically; and
a hooking part disposed on another side of the main body;
wherein, when the electronic element is pushed in the accommodating space, one end of the electronic element enters the blocking part and the other end of the electronic element presses the hooking part, so that the electronic element is accommodated in the accommodating space, and the hooking part hooks the other end of the electronic element.

2. The carrying structure of claim 1, wherein the electronic element is an optical disk drive or a hard disk drive.

3. The carrying structure of claim 1, wherein the blocking part has an opening, and the one end of the electronic element enters the blocking part through the opening.

4. The carrying structure of claim 1, wherein the casing has a sliding slot, a first opening and a second opening, and the main body correspondingly has a sliding rail, a first protrusion and a second protrusion, which are disposed corresponding to the sliding slot, the first opening and the second opening for fixing the main body on the casing.

5. The carrying structure of claim 1, wherein the main body further has a hand-held portion.

6. An electronic apparatus, comprising:
a casing; and
a carrying structure used to fix an electronic element on the casing, the carrying structure comprising:
a main body fixed on the casing and having an accommodating space for accommodating the electronic element,
a blocking part disposed on one side of the main body and configured to block the electronic element from moving vertically, and
a hooking part disposed on another side of the main body;
wherein, when the electronic element is pushed in the accommodating space, one end of the electronic element enters the blocking part and the other end of the electronic element presses the hooking part, so that the electronic element is accommodated in the accommodating space, and the hooking part hooks the other end of the electronic element.

7. The electronic apparatus of claim 6, wherein the electronic element is an optical disk drive or a hard disk drive.

8. The electronic apparatus of claim 6, wherein the blocking part has an opening, and the one end of the electronic element enters the blocking part through the opening.

9. The electronic apparatus of claim 6, wherein the casing has a sliding slot, a first opening and a second opening, and the main body correspondingly has a sliding rail, a first protrusion and a second protrusion, which are disposed corresponding to the sliding slot, the first opening and the second opening for fixing the main body on the casing.

10. The electronic apparatus of claim 6, wherein the main body further has a hand-held portion.

11. The electronic apparatus of claim 6, wherein the electronic apparatus is an all-in-one desktop computer.
